(19) United States
(12) Patent Application Publication
(10) Pub. No.: US 2010/0212198 A1
(43) Pub. Date: Aug. 26, 2010

(54) SURFACE EMITTER AND INTERNALLY ILLUMINATED SIGN INCORPORATING THE SAME

(76) Inventors: Hideto Matsunaga, Shizuoka (JP); Masaru Tsukamoto, Shizuoka (JP); Nobuyuki Koizumi, Shizuoka (JP); Daisuke Ikeda, Yaizu (JP)

Correspondence Address: OLIFF & BERRIDGE, PLC, P.O. BOX 320850, ALEXANDRIA, VA, 22320-4850, US

(21) Appl. No.: 12/734,096

(22) PCT Filed: Mar. 25, 2008
(86) PCT No.: PCT/JP2008/055539

§ 371 Date: Apr. 22, 2010

(30) Foreign Application Priority Data
Oct. 22, 2007 (JP) 2007-274094

(51) Int. Cl. G09F 13/04; H01L 33/62

(52) U.S. Cl. 40/564; 257/88; 257/E33.066

(57) ABSTRACT

To provide a novel surface emitter incorporating an LED element improved in waterproofness or other practical functionality to enable the surface emitter to be used not only for a sign but also for other various applications, in appearance and in workability, and an internally illuminated sign incorporating the same surface emitter. A surface emitter 1 according to the present invention has a flexible substrate 11 having electric wiring 12, a plurality of LED elements 13 disposed substantially regularly on the substrate 11, and a top film 14 disposed on the LED elements 13 in a stretched manner. When the top film 14 is disposed on the substrate 11 in a stretched manner, the top film 14 is applied to the substrate 11 to come into close contact with projections and depressions formed by the LED elements 13. More specifically, a vacuum pressure bonding process is used in which a space between the LED elements 13 and the top film 14 is evacuated, and the top film 14 is heated and pressure-bonded to the surface of the LED elements 13.

### TECHNICAL FIELD

The present invention generally relates to a surface emitter comprising a flexible substrate and a plurality of LED elements mounted thereon. In particular, it relates to a novel surface emitter significantly improved in practical functionality and practical applicability and an internally illuminated sign incorporating the same.

### BACKGROUND ART

Many conventional outdoor signs (internally illuminated signs) mounted on the wall of a building or the like use fluorescent lamps. However, signs using fluorescent lamps have disadvantages that they require a large installation space, have to have a size (thickness) enough to accommodate the fluorescent lamps and consume an excessive amount of power. Thus, the internally illuminated signs are gradually shifting to the use of LED elements that consume lower power (see Patent Document 1, for example). Of course, the internally illuminated signs are shifting from the fluorescent lamp type to the LED type not only in order to save energy as described above but also largely because the blue LED has been, put to practical use to enable various color representations, and the unit price of the LED element has become relatively low.

According to Patent Document 1 described above, a transparent plastic film (a top film 14′) is disposed in a stretched manner on LED elements 13′ mounted on a substrate 11′ as shown in FIG. 8. In practical use, however, the technique disclosed in Patent Document 1 requires further improvements as described below.

For a surface emitter 1′ according to Patent Document 1, as shown in FIG. 8, when the top film 14′ is disposed in a stretched manner, the top film 14′ with a hot melt (adhesive) (a polyvinyl chloride hot melt laminate film (75 microns) available from GMP Co. Ltd, Korea; for example) is laid on the substrate 11′ on which the LED elements 13′ are mounted, and the resulting laminate is pressed between a pair of pressure rollers R to apply the top film 14′ to the substrate 11′ (this process will be referred to a pressure treatment with a hot laminator hereinafter).

However, the LED elements 13′ form projections and depressions on the surface of the substrate 11′, so that air can be trapped (an air cavity ar occurs) between the LED elements 13′ and the top film 14′ in the pressure treatment with the hot laminator described above. If the air expands due to the externally applied heat, the LED elements 13′ can be detached or fail to light.

In addition, in the pressure treatment with the hot laminator, when the top film 14′ is pressed against the LED elements 13′ with the pressure rollers, the top film 14 can tear on a corner of an LED element 13′ (a corner of a casing) to compromise the waterproofness.

In addition, of course, the amount of air in the air cavity ar varies among the LED elements 13′. Therefore, if the LED elements 13′ are turned on in this condition, light emission from the LED elements 13′ is non-uniform (because different amounts of air in the air cavities ar cause non-uniform diffuse reflections of the light from the LED elements 13′) and makes people feel unbalanced or uncomfortable. That is, the air cavities ar formed between the LED elements 13′ and the top film 14′ can be undesirable in terms of appearance and visual effect of the sign. In particular, when the LED elements 13′ (and the substrate 11′) are used for lighting without being contained in a housing, people see the direct light from the LED elements 13′, and thus, the uncomfortable feeling caused by the air cavities ar becomes worse.

Furthermore, according to Patent Document 1 described above, as shown in FIG. 9 electric wiring 12 used to energize the LED elements 13′ form circuitry including a parallel arrangement of a plurality of series circuits each including a several LED elements 13′. In this case, for example, if a working hole (a cutout part FC) is formed at the center of the circuitry, some LED elements 13′ fail to light. Thus, the surface emitter 1′ according to Patent Document 1 also requires an improvement of the workability.

Patent Document 1: Japanese Patent Laid-Open No. 2007-33662

### DISCLOSURE OF THE INVENTION

### Problems to be Solved by the Invention

The present invention has been devised in view of such circumstances, and an object of the present invention is to provide a novel surface emitter incorporating an LED element improved in waterproofness or other practical functionality to enable the surface emitter to be used not only for a sign but also for other various applications, improved in appearance to directly raise the advertising effect, or improved in workability or the like in interior finish work or the like, and an internally illuminated sign incorporating the same surface emitter.

### Means for Solving the Problems

A surface emitter according to claim 1 is a surface emitter, comprising: a flexible substrate having electric wiring; a plurality of LED elements disposed substantially regularly on the substrate; and a top film disposed on the LED elements in a stretched manner, wherein when the top film is disposed on the substrate in a stretched manner, the top film is applied to the substrate to come into close contact with projections and depressions formed by the LED elements.

A surface emitter according to claim 2 is the surface emitter according to claim 1 that is further characterized in that when the top film is disposed on the substrate in a stretched manner to come into close contact with the projections and depressions formed by the LED elements, a space between the LED elements and the top film is evacuated, and the top film is heated and pressure-bonded to the surface of the LED elements.

A surface emitter according to claim 3 is the surface emitter according to any one of claim 1 or 2 that is further characterized in that the top film is a highly clingy and highly stretchable polyvinyl chloride film.

A surface emitter according to claim 4 is the surface emitter according to any one of claims 1, 2 and 3 that is further characterized in that the electric wiring that energizes the plurality of LED elements forms a mesh-shaped circuit, and even when a part of the circuit is cut out, the circuit supplies a current to a remaining LED element through a path bypassing the cutout part.

A surface emitter according to claim 5 is the surface emitter according to any one of claims 1, 2, 3 and 4 that is further characterized in that the top film is not only a transparent film but also is a material having a low transparency, such as an obscure glass sheet, a frosted glass sheet, an interior wallpaper, and a printed material.

An internally illuminated sign according to claim 6 is an internally illuminated sign, comprising: a sign case having a sign front surface, a side plate and a back plate; and the surface emitter according to any one of claims 1, 2, 3, 4 and 5 installed in the sign case.

### ADVANTAGES OF THE INVENTION

The object described above is attained by the configurations of the present invention described in the claims.

According to the aspect of the present invention according to claim 1, since the top film is applied to come into close contact with the projections and depressions formed by the LED elements, air can be prevented from being trapped (to form an air cavity) in the space between the LED elements and the top film. Therefore, the force to secure the LED elements can be increased, and the LED elements less susceptible to external heat. If an air cavity occurs, the air can expand due to external heat to cause the LED elements to slightly move (rattle). In this case (if the LED elements rattle), the force to secure the LED elements can decrease, and the LED elements can be detached from the substrate. However, the present invention eliminates the concern. Since no air cavity occurs, non-uniform diffuse reflection by air also does not occur, and thus, the appearance of the surface emitter is improved.

According to the aspect of the present invention according to claim 2, since the top film heated and having an increased elongation percentage is disposed in a stretched manner by so-called vacuum pressure bonding that involves evacuating the space between the LED elements and the top film, the top film disposed in a stretched manner can come into close contact with the projections and depressions formed by the LED elements with higher reliability.

According to the aspect of the present invention according to claim 3, the top film is a highly clingy and highly stretchable polyvinyl chloride film. The combination of the highly clingy and highly stretchable polyvinyl chloride film and the vacuum pressure bonding described above allows the top film to come into close contact with the projections and depressions formed by the LED elements with higher reliability, improves the waterproofness of the surface emitter, and increases the force to secure the LED elements.

The highly clingy and highly stretchable polyvinyl chloride film (a 100-micron film manufactured by HIROSHIMA KASEI, LTD., for example) has no pinhole in the material and thus can be considered as making a large contribution to the improvement of the waterproofness. More specifically, since the film has no pinhole, the film disposed on the substrate in a stretched manner can prevent water from entering (penetrating to) the side of the LED elements from the outside with high reliability, thereby significantly improving the waterproofness. In a test carried out by the applicant in which the surface emitter with the film is immersed in water for four months, it has been confirmed that penetration of water into the surface emitter does not occur, and the surface emitter has high waterproofness. Thus, the surface emitter can be installed outdoors or at a place where the surface emitter gets wet (on a wall of a bathroom, for example) without being housed in a case (housing) or the like (that is, in an exposed manner). Thus, the surface emitter can have a wide variety of extremely novel applications and can have many product variations.

According to the aspect of the present invention according to claim 4, the electric wiring is a mesh-shaped circuit. Thus, even if the electric wiring is partially cut out, the remaining LED elements can be energized through a path bypassing the cutout part and turned on and off. Therefore, in the case where the surface emitter is used as an interior material for a building, a part of the surface emitter (one unit) can be appropriately cut out to accommodate a receptacle or the like, and thus, the workability of the surface emitter is significantly improved. Of course, the surface emitter can be installed at an internal corner or an external corner.

Although LED elements generally have a long life, they burn out once in a while. According to the present invention, even when an LED element burns out, the other LED elements can be kept lighting. Many of the conventional surface emitters have electric wiring that turns off all the LED elements or part of the LED elements (a row of LED elements, for example) including the burnt out one when one LED element burns out.

According to the aspect of the present invention according to claim 5, the top film is not the ordinary transparent film but a material having a low transparency, such as an obscure glass sheet. Therefore, the surface emitter can be used for a novel application, such as a household interior material, and can have many product variations. For example, if the top film is an interior wallpaper, the LED elements are hardly recognizable during the daytime when the LED elements are turned off, and thus, the top film serves to conceal the LED elements (the top film has a kind of camouflage effect). However, at night, the wallpaper used as the top film soften the light from the LED elements to create a comfortable atmosphere like indirect lighting (the top film has a kind of healing effect). Thus, the surface emitter can be used not only for lighting of a sign but also as an interior material (wallpaper or the like) that has a surprising effect.

Of course, the concept that the surface emitter is used as an interior material and installed on a wall leads to a novel technical concept of providing a wall with a lighting capability, or in other words, a novel technical concept of extremely thin lighting. If a conventional fluorescent lamp or the like is installed on a wall, the wall has to have an enough thickness to accommodate the lamp embedded therein. However, according to the present invention, the wall no longer has to have such a large thickness. In addition, the present invention does not require a lighting box or the like that is needed to install the fluorescent lamp. Furthermore, works involved with installing the fluorescent lamp, such as forming holes in a wall, are not necessary, and the surface emitter according to the present invention can be extremely easily installed. Of course, the concept (idea) of the thin lighting apparatus can also be applied to conventional lighting (ceiling lighting) attached a ceiling surface.

Although the obscure glass sheet, the frosted glass sheet and the like have low transparency, they transmit light (sunlight) to some extent. Thus, the surface emitter with these sheets as the top film can be attached to an ordinary glass window, a skylight, a see-through floor or the like to provide both daylighting during the daytime and decorative lighting at night.

The “printed material” described in claim 5 is not limited to a top film on which an appropriate pattern is previously printed but may be a top film on which an appropriate pattern is printed after vacuum pressure bonding.

According to the aspect of the present invention according to claim 6, the internally illuminated sign incorporates the surface emitter according to any of claims 1 to 5. Thus, the internally illuminated sign has a good appearance and a small thickness (thin decorative lighting). That is, dots of the LEDs elements are invisible, and the thin decorative lighting emits light with uniform brightness. The thin decorative lighting can be safely installed anywhere because it does not obstruct pedestrians or hit a child in the head. In addition, since the surface emitter itself has high waterproofness, the thin decorative lighting is also highly waterproof and can be installed at a place where the waterproofness of the sign case can hardly be ensured because of the shape of the wall of the building on which the sign is installed, for example.

### BRIEF DESCRIPTION OF THE DRAWINGS

FIG. 1(a) is a perspective view of an internally illuminated sign incorporating a surface emitter according to the present invention;

FIG. 1(b) is an enlarged cross-sectional view of the internally illuminated sign viewed from the direction of the arrow A in FIG. 1(a);

FIG. 2(a) is a front view of a unit forming the surface emitter;

FIG. 2(b) is a cross-sectional view of the unit showing a frame thereof;

FIG. 3 includes diagrams for illustrating steps of a vacuum pressure bonding process used to dispose a top film in a stretched manner on a substrate to come into close contact with the substrate;

FIG. 4 includes diagrams for illustrating an example of a mesh-shaped circuit that energizes a remaining LED element through a path bypassing a cutout part;

FIG. 5 includes diagrams for illustrating another example of the mesh-shaped circuit;

FIG. 6 includes diagrams for illustrating another example of the mesh-shaped circuit;

FIG. 7 is a diagram for illustrating an application of the surface emitter according to the present invention as a panel of a grid ceiling system;

FIG. 8 is a diagram for illustrating a method of disposing a top film of a conventional surface emitter in a stretched manner (under pressure with a hot laminator); and

FIG. 9 is a diagram for illustrating lighting of the remaining LED elements of a conventional surface emitter that is partially cut out.

### DESCRIPTION OF SYMBOLS

1 surface emitter
1a intermediate product
2 sign case
4 vacuum pressure bonding apparatus
11 substrate
12 electric wiring (printed wiring)
13 LED element
14 top film
15 aluminum plate
16 constant current circuit
21 sign front surface
22 side plate
23 back plate
41A upper box
41AR sealed space
41B lower box
41BR sealed space
42 electric heater
43 lifting table
44 pressurized air tank
45 vacuum tank
46 switch valve
ar air cavity
F frame
FC cutout part
R pressure roller
SB internally illuminated sign

### BEST MODE FOR CARRYING OUT THE INVENTION

Best modes for carrying out the present invention include the embodiment described below as an example and include various improvements that can be made without departing from the technical spirit of the present invention.

In the following, a general configuration of a surface emitter 1 will be first described, and then, characteristic features of the present invention will be described. And then, an internally illuminated sign SB incorporating the surface emitter 1 and other applications of the surface emitter 1 will be described.

### Embodiment

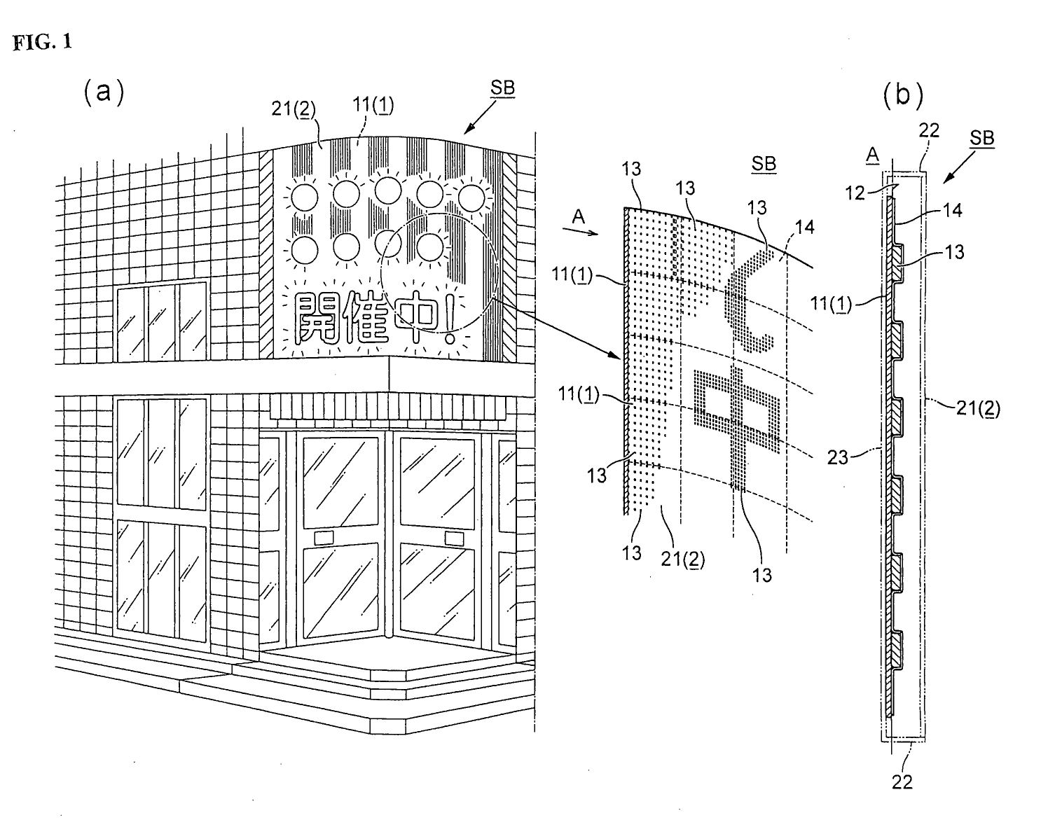

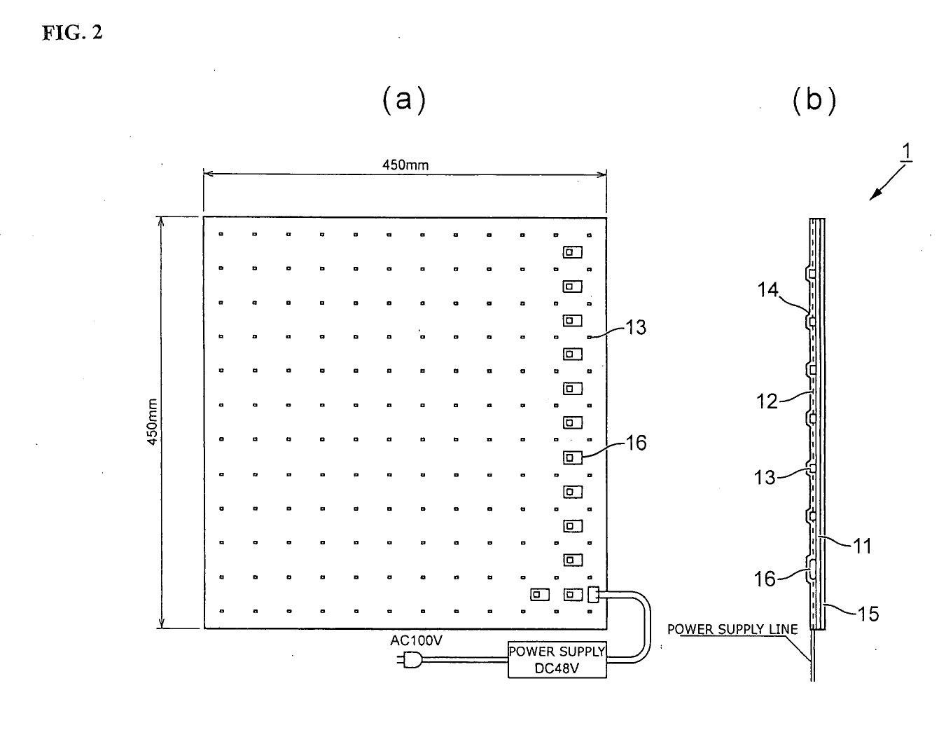

As shown in FIGS. 1 and 2, for example, a surface emitter 1 according to the present invention comprises a flexible substrate 11 having electric wiring 12, a plurality of LED elements 13 substantially regularly arranged on the substrate 11, and a top film 14 disposed in a stretched manner on the substrate 11 to cover the LED elements 13. In the following, the components will be individually described.

First, the substrate 11 will be described. The substrate 11 is a base member on which the LED elements 13 are regularly attached (mounted), has the shape of a film or a sheet, and can be made of various kinds of flexible insulating materials. In general, the substrate 11 is made of plastic (a synthetic resin) that is superior in handleability and workability. In particular, polyethylene terephthalate, polyester, polyimide, polyvinyl chloride, epoxy resin and the like that are superior in heat resistance, light resistance, mechanical strength and the like are preferably used. In particular, a white PET film is used as the substrate 11 in this embodiment.

The electric wiring 12 intended to energize and turn on and off the LED elements 13 is formed on the substrate 11. In this embodiment, the wiring 12 is patterned to be able to turn on and off all the remaining LED elements 13 even when the circuit is partially cut out to form a working hole in the substrate 11 (surface emitter 1), as described later.

For example, desired electric wiring 12 can be formed on the substrate 11 by printing a predetermined appropriate wiring pattern on one surface of a film-shaped or sheet-shaped member (referred to as print wiring and denoted by the same reference numeral 12 as the electric wiring) and overlaying and applying the print wiring 12 onto the substrate 11. More specifically, for example, desired print wiring 12 is formed by screen-printing a conductive silver paste on a sheet-shaped member, and the sheet-shaped member with the print wiring 12 is bonded to the substrate 11 to form the electric wiring 12 on the substrate 11. Of course, the electric wiring 12 can be formed on the substrate 11 not only by such printing process but also by any other processes, such as vapor deposition and etching.

Next, the LED elements 13 serving as a light source will be described. A plurality of LED elements 13 is regularly disposed on the substrate 11. In this embodiment, in particular, the substrate 11 on which a plurality of LED elements 13 is arranged at regular intervals in both the vertical direction and the horizontal direction is regarded as a unit as shown in FIG. 2. And a plurality of units is coupled (connected) to each other, or one unit is cut, for practical use. The plurality of LED elements 13 is arranged at regular intervals in both the vertical direction and the horizontal direction in order to improve the versatility (workability) of the unit and make dots of the LED elements 13 invisible and prevent non-uniform light when the unit is applied to a sign.

In addition, unitization of the surface emitter 1 has an advantage that it improves the ease of wiring or installation.

For example, one unit of the surface emitter 1 comprises a 450-mm-by-450-mm-square substrate 11 and 12 by 12 (144) LED elements 13 regularly mounted on the substrate 11 (the unit weighs about 280 g, for example). Even when one unit of the surface emitter 1 is cut for use in a sign or the like, for example, the resulting surface emitter 1 preferably has at least about 24 LED elements 13 (at least two rows of LED elements 13, for example). In the case where one unit of the surface emitter 1 is cut in the row direction (into a part including two or three rows, for example), the distance between the outer edge of the resulting substrate 11 and the outermost LED element 13 is preferably about a half of the interval between the LED elements 13, from the viewpoint of appearance or the like.

Of course, the unit of the surface emitter 1 may not be the 450-mm-by-450-mm-square unit (including 12 rows of LED elements) described above, which is appropriately cut for use. Alternatively, several units of different patterns may be put into commercial production. For example, in addition to the 450-mm-by-450-mm unit (including 12 rows) described above, the applicant is contemplating a 450-mm-by-225-mm unit (including 6 rows), a 450-mm-by-187.5-mm unit (including 5 rows), a 450-mm-by-150-mm unit (including 4 rows), a 450-mm-by-112.5-mm unit (including 3 rows), and a 450-mm-by-75-mm unit (including 2 rows) as standard unit patterns, for example.

The LED element 13 is NSSW100C manufactured by Nichia Corporation, for example, and has a light emission angle (so-called view angle) of about 60 degrees to about 120 degrees. The LED element 13 (a casing thereof) preferably has a circular planar shape or a rectangular planar shape. In this embodiment, the vertical and horizontal distances between the LED elements 13 of one unit of the surface emitter 1 are about 37.5 mm (450 mm divided by 12). However, the distance can be appropriately changed within a range from 10 mm to 60 mm, for example. Furthermore, the LED elements 13 can be mounted on the substrate 11 with the electric wiring 12 by a fixing process (a bonding process) using solder, adhesive or the like.

The color of the LED elements 13 may vary according to production lot, even if the LED elements 13 are designed to emit light of the same color. Therefore, the LED elements 13 from the same production lot are preferably used in the same surface emitter 1.

Next, the top film 14 will be described. The top film 14 covers the top of the substrate 11 on which the LED elements 13 are mounted to form a laminate, primarily aiming at improving the waterproofness of the surface emitter 1. In addition to this aim, the top film 14 serves also to protect the LED elements 13 (the surface emitter 1) against an external force or sunlight and reinforce the LED elements 13, for example.

The top film 14 may be a transparent plastic sheet having high transparency or may be an obscure glass sheet, a frosted glass sheet, interior cloth, a printed material or the like that is made of a material having low transparency. The material of the top film 14 can be appropriately selected for use mainly depending on the application (use) of the surface emitter 1. The conventional surface emitter is supposed to be incorporated in a sign (an internally illuminated sign), so that the top film is limited to a transparent plastic sheet that transmits the light from the LED elements without significant loss. However, according to the present invention, the surface emitter 1 is not only incorporated in a sign but also installed outdoor installation (without a housing), used as a wall, a floor or a partition in a shop or a room, or used for lighting of a tapestry or a window, for example, and thus, various types of top films 14 are contemplated. In other words, the present invention significantly improves the waterproofness of the surface emitter 1 in order to expand the application of the surface emitter 1 to other uses than a sign (internally illuminated sign SB). The improvement of the waterproofness allows the surface emitter 1 to be used in a bathroom or other indoor place where the surface emitter 1 gets wet or on a window on which condensation occurs or to be used as a bottom or a side wall of a pool, a water reservoir, a water tank or the like. In the case where the surface emitter 1 is used as an interior wall material, it is conceptually close to a lighting wall (a lighting interior material) rather than the surface emitter. That is, it can be considered as a wall having a lighting capability or an interior material having a lighting capability, which is an extremely novel interior material (surface emitter).

Of the various types of top films 14 described above, the transparent plastic sheet transmits the light from the LED elements 13 without significant loss and therefore is mainly used for applications in which the surface emitter 1 is incorporated in a sign (internally illuminated sign SB) as described above.

The obscure glass sheet and the frosted glass sheet do not significantly block sunlight and therefore are suitably applied to a case where the surface emitter 1 is provided on a glass window of a shop, for example. That is, the surface emitter 1 can ensure sufficient daylighting of the shop during the daytime and provide decorative lighting of the glass window at night. Of course, the obscure glass sheet and the like make the LED elements 13 less recognizable, so that the LED elements 13 are unobtrusive when the LED elements 13 are turned off. Thus, the LED elements 13 installed on a glass window, a wall or the like are matched to the atmosphere of the shop or room and create a comfortable atmosphere in the space.

The ordinary wallpaper or printed material substantially conceals the presence of the LED elements 13. When the LED elements 13 are turned on, the top film 14 softens the light to create a fantastic atmosphere. The wallpaper or printed material can be in the form of an elongated sheet.

The top film 14 is preferably made of a material having a high mechanical strength, a high weather resistance (waterproofness, heat resistance, light resistance and the like) and a high workability. For example, the material may be polystyrene, polyester, polyvinyl chloride or ABS. In particular, a highly clingy and highly stretchable polyvinyl chloride film (a 100-micron film manufactured by HIROSHIMA KASEI, LTD., for example) is preferably used in this embodiment. The highly clingy and highly stretchable polyvinyl chloride film has no pinhole in the material and therefore can be considered to make a large contribution to improvement of the waterproofness.

When the top film 14 is disposed on the substrate 11 (the LED elements 13) in a stretched manner, the film is applied to come into close contact with the projections and depressions formed by the LED elements 13 to prevent air from being trapped between the LED elements 13 and the top film 14. A specific method therefor will be described later.

The surface emitter 1 can have another member in addition to the essential members described above. In the following, such members will be described (see FIG. 2).

For example, the surface emitter 1 may have an aluminum plate 15 having a thickness of about 0.5 mm provided on the opposite surface of the substrate 11 to the LED elements 13 (referred to as a back surface) with a gluing agent (double-sided) interposed therebetween. The surface emitter 1 may further have an adhesive film on the back surface of the aluminum plate 15. The aluminum plate 15 having a thickness of about 0.5 mm is provided to stabilize the surface emitter 1 and improve the workability thereof. In particular, in the case where the surface emitter 1 is used as an interior material, it is practical to substitute an aluminum foil (aluminum tape) or the like for the aluminum plate 15. The gluing agent is a bonding agent (adhesive) to apply the aluminum plate 15 to the substrate surface, and the adhesive film is provided to protect against rust. In the drawing, reference numeral 16 denotes a constant current circuit.

The surface emitter 1 has the basic configuration described above. In the following, characteristic features of the surface emitter 1 according to the present invention will be described.

(1) Tight Application of Top Film

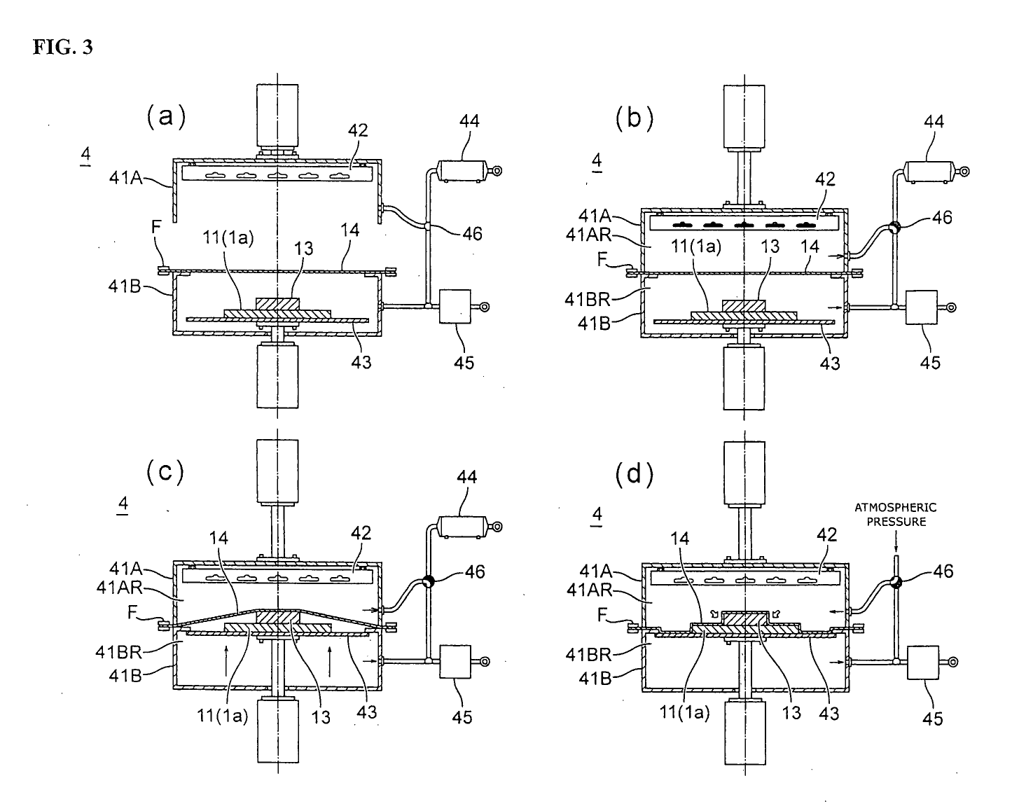

According to the present invention, the top film 14 is disposed in a stretched manner on the substrate 11 to come into close contact with and conform to the projections and depressions formed by the LED elements 13. More specifically, the film is disposed in a stretched manner on the substrate 11 while evacuating the space between the LED elements 13 and the top film 14 (vacuum pressure bonding). To achieve the vacuum pressure bonding, a vacuum pressure bonding apparatus 4 shown in FIG. 3 is used, for example. FIG. 3 includes diagrams for clearly illustrating the process of the vacuum pressure bonding, and the substrate 11 and the like to be subject to the bonding processing and the apparatus are scaled differently. The expression “to dispose (the top film 14) to come into close contact with” means to apply the top film 14 to the substrate 11 by preventing air from being trapped between the LED elements 13 and the top film 14 or, in other words, preventing an air cavity ar from occurring between the LED elements 13 and the top film 14. In the following, the vacuum pressure bonding apparatus 4 will be described.

The vacuum pressure bonding apparatus 4 shown in FIG. 3 is a kind of the so-called “Next Generation Forming; NGF” and has a pair of upper and lower boxes that can be sealed to each other. The upper box is denoted by reference numeral 41A, and the lower box is denoted by reference numeral 41B. The upper box 41A opens at the bottom, and the lower box opens at the top. When the upper box 41A and the lower box 41B abut against each other with the top film 14 to be disposed in a stretched manner on the substrate 11 interposed therebetween, a sealed space is formed therein. The sealed spaces formed in the upper and lower boxes are denoted by reference numerals 41AR and 41BR, respectively.

The upper box 41A is capable of vertically moving and houses an electric heater 42. The lower box 41B is fixed, and lifting table 43 capable of vertically moving is disposed in the lower box 41B. In the drawing, reference numeral 44 denotes a pressurized air tank, reference numeral 45 denotes a vacuum tank, and reference numeral 46 denotes a switch valve.

In the following, an operation of the vacuum pressure bonding apparatus 4 to dispose the top film 14 in a stretched manner on the substrate 11 to come into close contact therewith will be described.

[1] Preparation

Before starting the processing, a preparation is performed as described below. First, as shown in FIG. 3(a), when the lower box 41B is spaced apart from the upper box 41A and is open, the substrate 11 with the LED elements 13 (referred to as an intermediate product 1a) is mounted on the lifting table 43 in the lower box 41B. Then, the top film 14 held by a frame F is placed on the top of the lower box 41B to cover the top of the lower box 41B.

[2] Heating (in Vacuum)

Then, as shown in FIG. 3(b), the upper box 41A is lowered to hold the top film 14 between the upper box 41A and the lower box 41B. At this time, the separate sealed spaces 41AR and 41BR are formed on the opposite sides of the top film 14 in the upper box 41A and the lower box 41B. Then, the switch valve 46 is manipulated to make the vacuum tank 45 able to operate on the sealed space 41AR as well, and then, the sealed spaces 41AR and 41BR are evacuated simultaneously.

Then, when both the sealed spaces 41AR and 41BR are evacuated to a certain level, the electric heater 42 in the upper box 41A is turned on to heat the top film 14.

[3] Primary Molding

When the top film 14 is heated to a desired molding temperature (which is preferably a temperature at which the elongation percentage of the film is at the maximum), as shown in FIG. 3(c), the lifting table 43 in the lower box 41B is lifted to perform primary molding. In the primary molding, the top film 14 is in contact with the highest part (top surface) of the intermediate product 1a as shown in the drawing.

[4] Secondary Molding

Then, the vacuum in the interior of the upper box 41A (sealed space 41AR) is released. To achieve this, as shown in FIG. 3(d), the switch valve 46 is manipulated to open the sealed space 41AR to the atmosphere, and then, air is introduced to the sealed space 41AR to bring the pressure in the upper box 41A to the atmospheric pressure. At this time, the interior of the lower box 41B or, in other words, the space below the top film 14 in which the intermediate product 1a is placed is still vacuum. Therefore, the top film 14 is pressed against the intermediate product 1a to come into close contact with corners thereof with reliability by the action of the atmospheric pressure in the upper box 41A or, in other words, the pressure difference between above and below the top film 14.

As described above, according to the present invention, the top film 14 is disposed in a stretched manner on the intermediate product 1a while evacuating the space between the top film 14 and the intermediate product 1a, so that no air is trapped between the film and the LED elements 13 (no air cavity ar occurs). In addition, the top film 14 is heated when the top film 14 is disposed in a stretched manner, so that the film is well stretched, and no wrinkle occurs, and therefore, the top film 14 comes into close contact with the projections and depressions formed by the LED elements 13. In addition, since the air cavity ar does not occur, the LED elements 13 are less susceptible to external heat. Conversely, if an air cavity ar occurs, the trapped air can expand due to external heat to cause detachment of the LED element 13. However, according to the present invention, since no air cavity ar occurs, there is no concern that an LED element 13 is detached. In addition, this processing does not involve using a roller or the like to press the top film 14 directly against the LED elements 13, so that there is no possibility that the film tears when the film is disposed in a stretched manner on the intermediate product 1a, of course.

(2) Application of Highly Clingy and Highly Stretchable Polyvinyl Chloride Film as Top Film

According to the present invention, the top film 14 is preferably a highly clingy and highly stretchable polyvinyl chloride film (a 100-micron film manufactured by HIROSHIMA KASEI, LTD., for example). The combination of this film and the vacuum pressure bonding process described above allows the top film 14 to come into substantially perfect contact with the projections and depressions formed by the LED elements 13. That is, the top film 14 is a thick film (which is about 4/3 times thicker than a conventional film, for example) and is significantly superior in stretchability. Thus, the top film 14 is suitable for the vacuum pressure bonding that involves high elongation percentage of the film and can satisfactorily come into close contact with the projections and depressions formed by the LED elements 13.

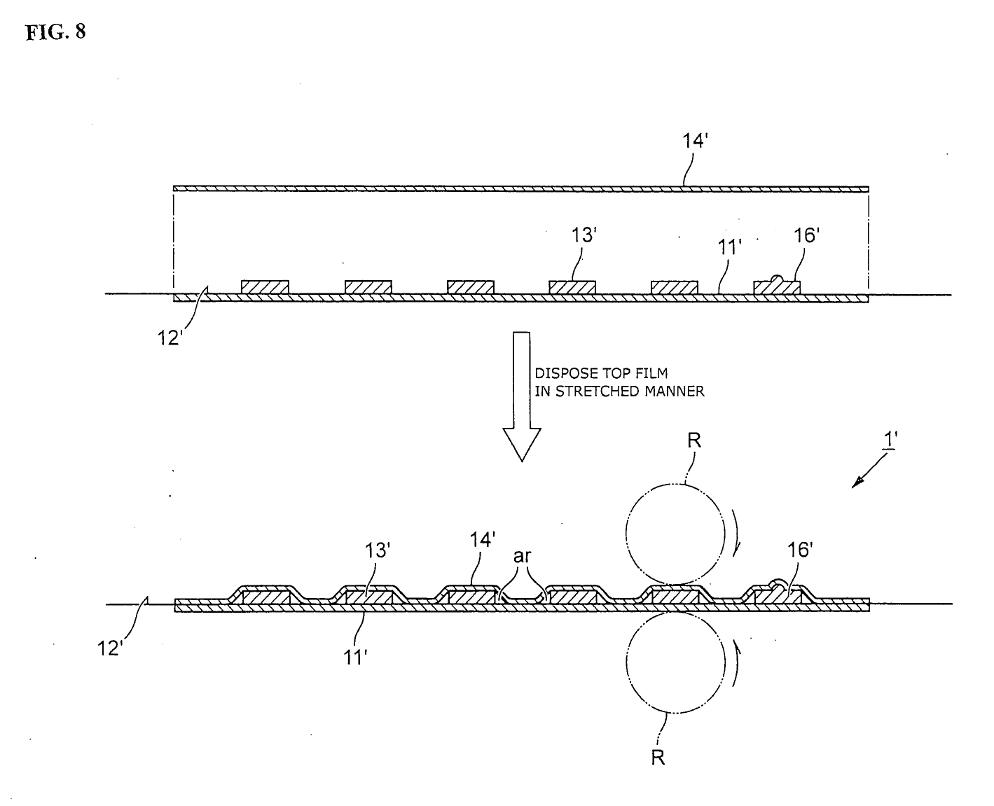

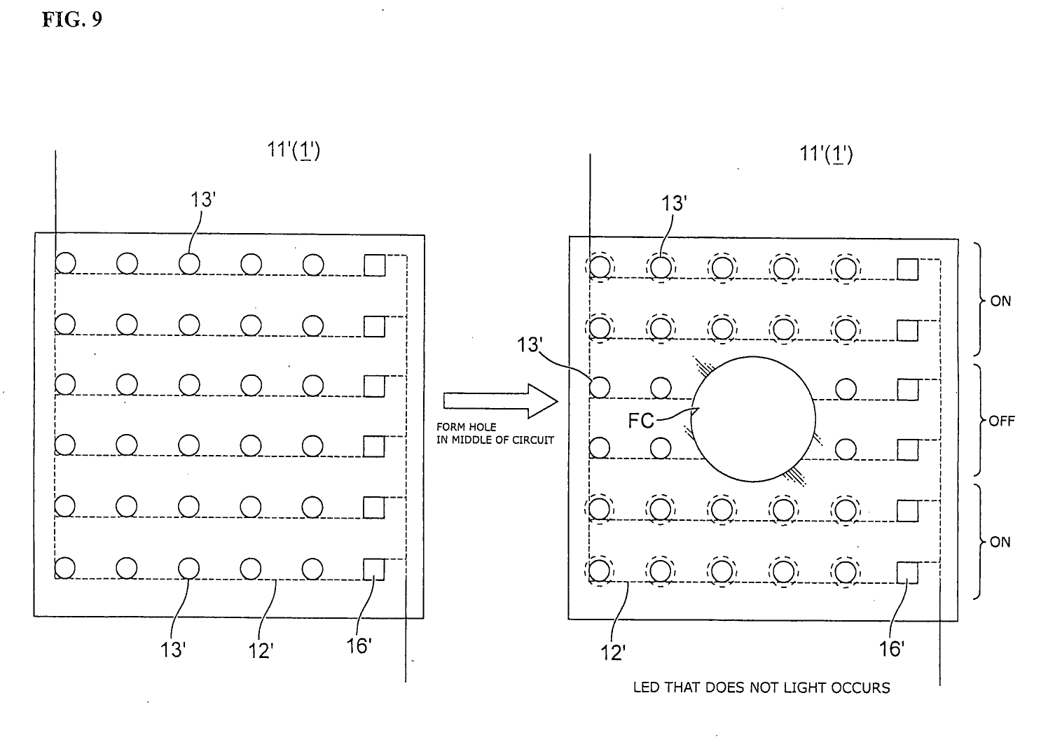

To the contrary, the conventional top film 14′ (see FIG. 8) is thin and inferior in stretchability (shrinkability). Thus, even if the vacuum pressure bonding is used to apply the conventional top film 14′ to the substrate 11, the film cannot come into close contact with the projections and depressions formed by the LED elements 13. In other words, the conventional top film 14′ can be considered as being designed for pressure bonding with a hot laminator. If the vacuum pressure bonding described above is applied to the conventional top film 14′, the top film 14′ is extremely likely to tear in the vacuum pressure bonding because of the projections and depression formed by the LED elements 13, leading to an extremely low yield.

In addition, the highly clingy and highly stretchable polyvinyl chloride film described above has no pinhole in the material and thus can be considered as making a large contribution to improvement of the waterproofness. More specifically, since the film has no pinhole, the film disposed in a stretched manner on the substrate can prevent water from entering (penetrating to) the side of the LED elements 13 from the outside with high reliability, thereby significantly improving the waterproofness. In a test carried out by the applicant in which the surface emitter 1 with the film is immersed in water for four months, it has been confirmed that penetration of water into the surface emitter 1 does not occur, and the surface emitter 1 has high waterproofness. Thus, the surface emitter 1 can be installed outdoors or at a place where the surface emitter 1 gets wet (on a wall of a bathroom, for example) without being housed in a case or the like (that is, in an exposed manner). Thus, the surface emitter 1 can have a wide variety of extremely novel applications and can have many product variations.

The top film 14 (highly clingy and highly stretchable polyvinyl chloride film) is compliant with IP58. The number “5” in the notation “IP58” is a first identification number “5” that indicates the level of protection against solid matters or, in other words, the dustproof level. The level 5 means providing a protection against a detrimental amount of dust (dust control level). The number “8” in the notation “IP58” is a second identification number “8” that indicates the level of protection against water. The level of protection against water is graded into nine levels from the level 0 to the level 8. The levels 0 to 6 means that some water may enter the inside. The level 8 means the maximum waterproof level. The waterproof level 8 means preventing water from entering the inside even if immersed in water for a certain length of time (in-water level).

(3) Mesh-Shaped Electric Wiring

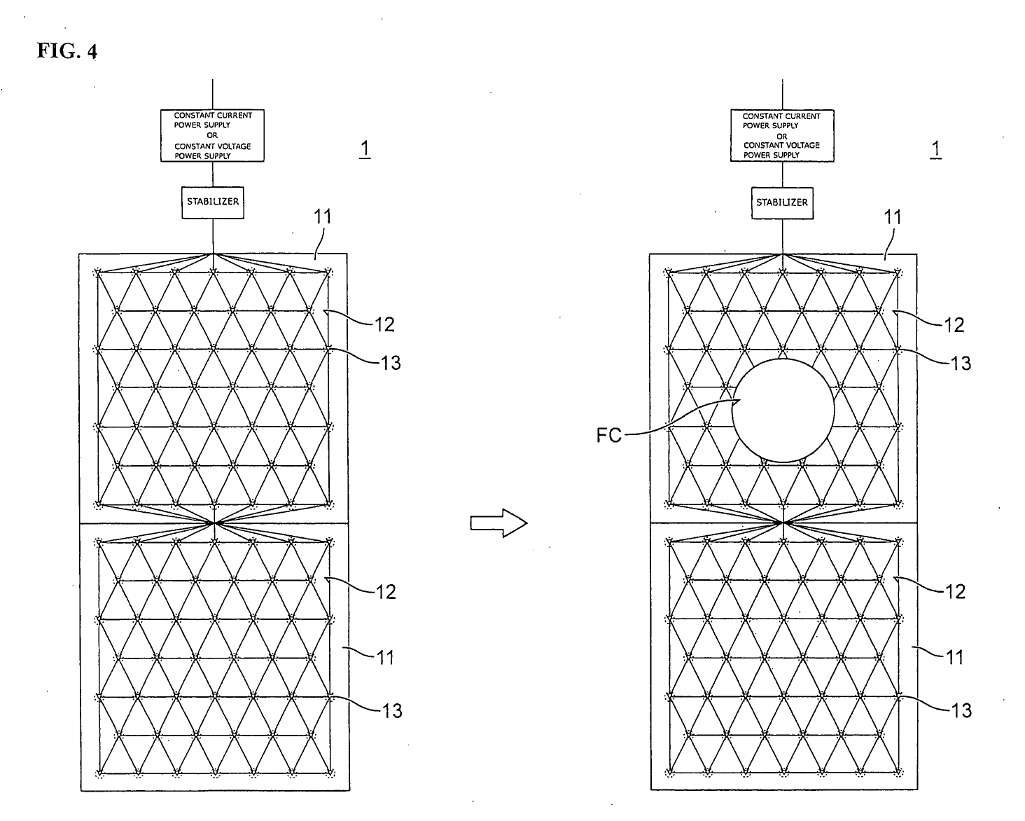

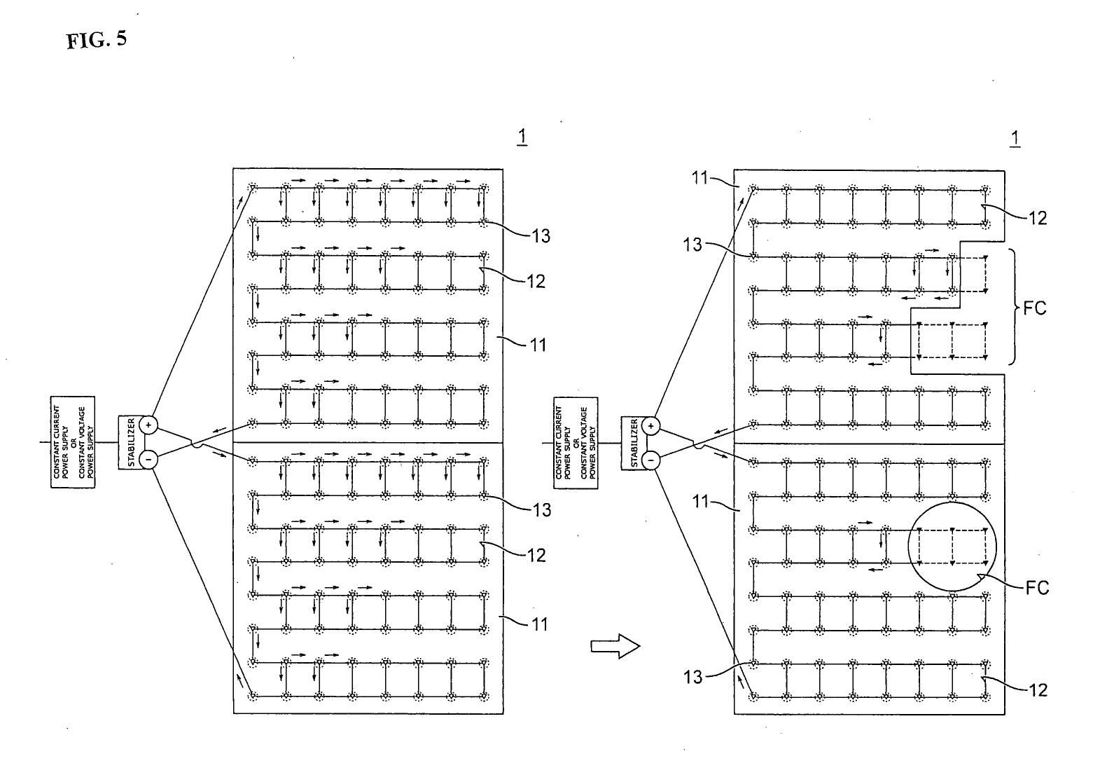

According to the present invention, the electric wiring 12 preferably forms a circuit that supplies a current to the remaining LED elements 13 along paths bypassing the cutout part FC even when a part of the electric wiring 12 is (arbitrarily) cut out (the circuit is referred to as a mesh-shaped circuit in this specification) (see FIGS. 4 to 6). In this case, even if the surface emitter 1 used as an interior material is partially cut out to accommodate a receptacle or the like, all the remaining LED elements 13 can be turned on, and thus, an extremely high workability can be achieved.

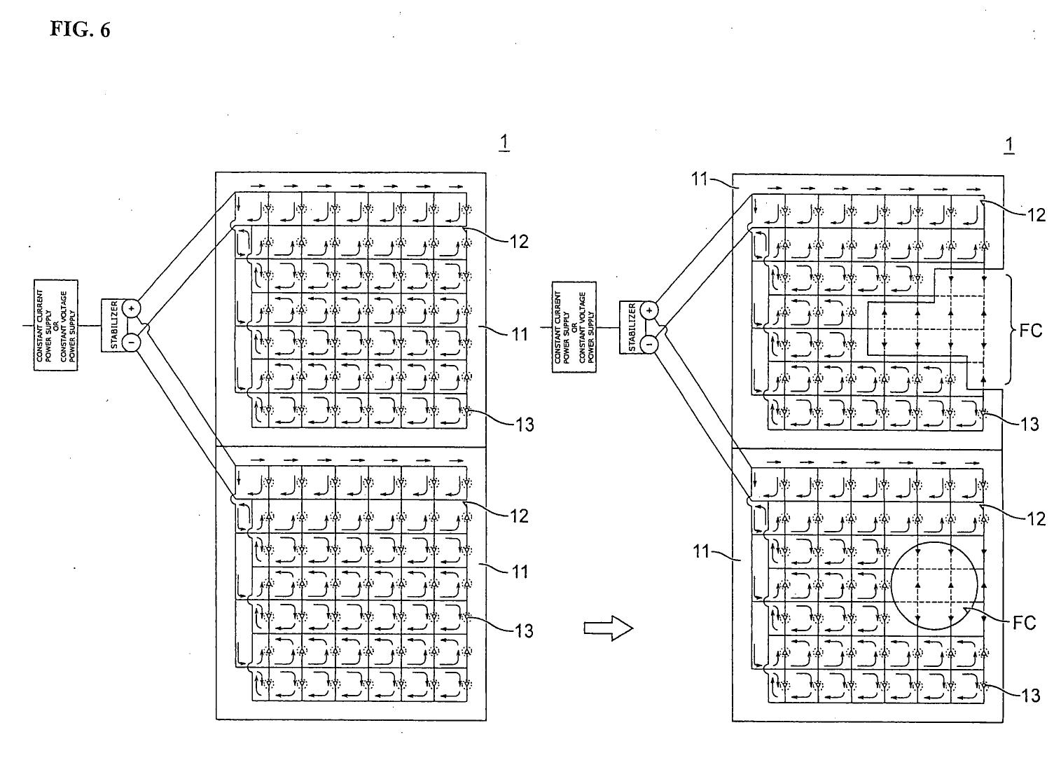

In the electric wiring 12 shown in FIG. 6, three LED elements 13 located at the right of the circular cutout part FC do not light. However, the three LED elements 13 are the outermost elements in the unit and thus do not have an adverse effect on the appearance in many cases. In other words, even when there is a difference between the actually formed cutout part FC and the LED element 13 that does not light, if the LED element 13 that does not light (that is located outside the cutout part FC) is the outermost element, the difference is not conspicuous in the dark and thus is seldom recognized by people. Even when the cutout part FC is located at the center of a large light emitting surface, if another unit is arranged adjacent thereto, the effect of the difference on the appearance can be considered extremely small. That is, in this case, a person who looks at the surface emitter 1 in the dark would think that a square cutout part FC is originally formed, and the nine LED elements are originally designed not to light, and thus feels less uncomfortable when the LED elements 13 are turned on.

The electric wiring 12 is preferably designed to make all the remaining LED elements 13 light with the same brightness regardless of the position of the cutout part FC in the electric wiring 12. To achieve this, for example, a controlling unit can be previously provided for each LED element 13 to control the current flowing to the LED elements 13 to be substantially uniform (a separate control method).

As an alternative to the separate control, for example, a stabilizer that controls the current flowing to the LED elements 13 may be previously provided at a position preceding the point where the current flows into the mesh-shaped circuit, and the current flowing to the LED elements 13 may be collectively controlled with the stabilizer when the mesh-shaped circuit is partially cut out.

In the following, an internally illuminated sign SB incorporating the surface emitter 1 will be described. The internally illuminated sign SB is the most typical application of the surface emitter 1. As shown in FIG. 1, the internally illuminated sign SB comprises a sign case 2 comprising a sign front surface 21, a side plate 22 and a back plate 23, and the surface emitter 1 described above installed in the sign case 2.

The sign front surface 21 is preferably a fabric sheet (FF sheet) or an acrylic fiber member, which is a member made of a strong fiber sandwiched between (or integrally molded with) translucent resin layers on the opposite sides thereof. The applicant has confirmed that in the case where the vertical and horizontal intervals between the LED elements 13 are about 37.5 mm as described above, the view angle falls within a range of about 105 degrees to 110 degrees, and the sign front surface 21 is formed by the FF sheet, the distance between the display surface and the LED elements 13 is about 50 mm, and dots of the LED elements 13 are invisible (the LED elements 13 uniformly diverge light). This enables production of a thin internally illuminated sign SB (thin decorative lighting) having a thickness of about 50 mm. In addition, the applicant has confirmed that in the case where an acrylic member having a thickness of about 5 mm is used for the sign front surface 21 (the other conditions are the same as those described above), the internally illuminated sign SB can have a smaller thickness of about 40 mm (35 mm to 38 mm).

The surface emitter 1 according to the present invention has various applications in addition to the internally illuminated sign SB. For example, if an obscure glass sheet, a frosted glass sheet, an interior wallpaper, a printed material or the like is used for the top film 14, the surface emitter 1 can be used as a household interior material. Furthermore, the surface emitter 1 not housed in the sign case 2 can be used outdoors. Furthermore, since the surface emitter 1 has high waterproofness, the surface emitter 1 can be used in a place where the surface emitter 1 gets wet, such as a bathroom. In particular, the concept that a wall, a window, a floor, a partition or other interior member emits light is an extremely novel concept, and such applications other than the sign are completely new applications of the surface emitter 1 that no one has come up with and can be said as one of the remarkable advantages of the present invention. Of course, the surface emitter 1 can be applied to an emergency exit sign or a handrail that can be used both indoors and outdoors.

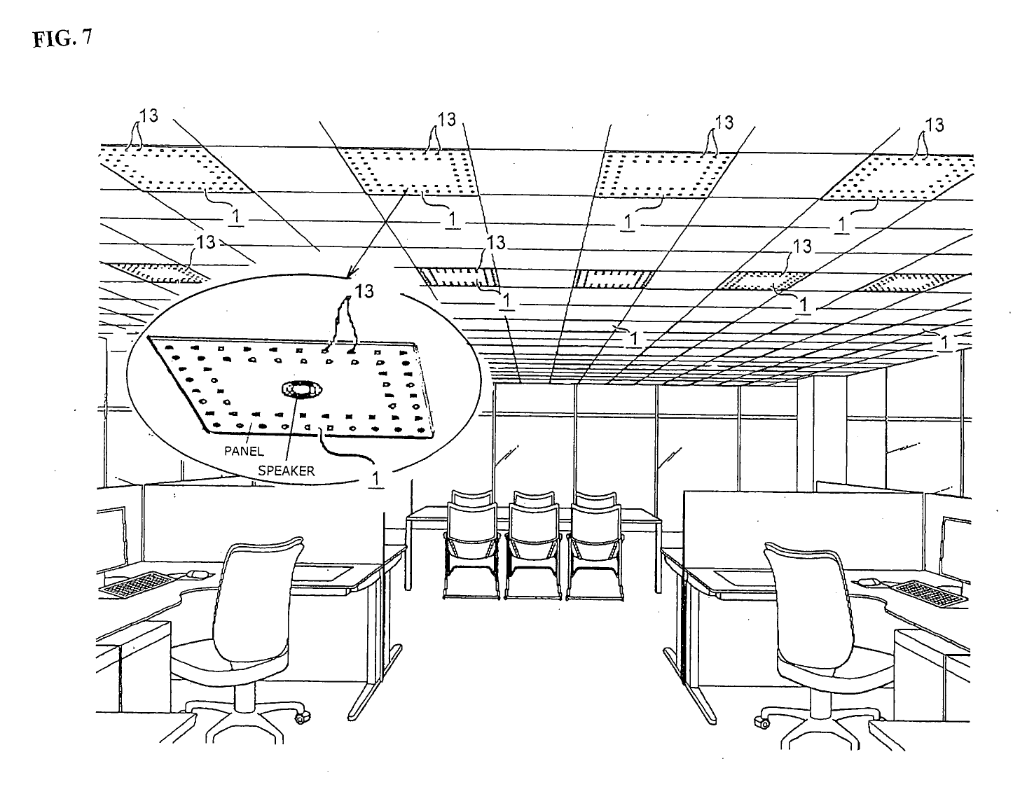

In addition, the surface emitter 1 according to the present invention can be applied to ceiling area lighting in a large office building or the like as shown in FIG. 7, for example. More specifically, FIG. 7 shows an example of a grid ceiling system in which the ceiling surface is formed by a matrix of a plurality of panels, each of which is formed by the surface emitter 1 according to the present invention on which LED elements 13 are appropriately arranged. As in the case where the surface emitter 1 is used as a wallpaper on a wall, no lighting box is needed, so that the ceiling area lighting is thin, and a neat and open interior space can be created.

The grid ceiling system typically has not only panels that have the lighting capability (surface emitters 1) but also panels that do not have the lighting capability, and the panels having the lighting capability are arranged at regular intervals. Alternatively, however, all the panels may have the lighting capability. In addition, each panel having the lighting capability typically does not have the LED elements 13 at the center thereof but has the LED elements 13 in a peripheral area. Thus, a speaker, an emergency light, a smoke detection sensor, an air conditioning diffuser or the like can be installed at the center of the panel where no LED elements 13 are disposed as required (see the enlarged view in FIG. 7).

The grid ceiling system in which lighting (panels having the lighting capability) are uniformly arranged has advantages that the brightness in the room can be easily adjusted, and an appropriate illuminance can be easily achieved everywhere in the room. In addition, the grid ceiling system has advantages that the floor can be partitioned without obstruction by the lighting, and an appropriate illuminance can be easily achieved regardless of how to partition the floor.

1-6. (canceled)

7. A surface emitter, comprising:
a flexible substrate having electric wiring;
a plurality of LED elements disposed substantially regularly on the substrate; and
a top film disposed on the LED elements in a stretched manner,
wherein when said top film is disposed on the substrate in a stretched manner, the top film is applied to the substrate to come into close contact with projections and depressions formed by the LED elements.

8. The surface emitter according to claim 7, wherein when said top film is disposed on the substrate in a stretched manner to come into close contact with the projections and depressions formed by the LED elements, a space between the LED elements and the top film is evacuated, and the top film is heated and pressure-bonded to the surface of the LED elements.

9. The surface emitter according to claim 7, wherein said top film is a highly clingy and highly stretchable polyvinyl chloride film.

10. The surface emitter according to claim 8, wherein said top film is a highly clingy and highly stretchable polyvinyl chloride film.

11. The surface emitter according to claim 7, wherein the electric wiring that energizes said plurality of LED elements forms a mesh-shaped circuit, and even when a part of the circuit is cut out, the circuit supplies a current to a remaining LED element through a path bypassing the cutout part.

12. The surface emitter according to claim 8, wherein the electric wiring that energizes said plurality of LED elements forms a mesh-shaped circuit, and even when a part of the circuit is cut out, the circuit supplies a current to a remaining LED element through a path bypassing the cutout part.

13. The surface emitter according to claim 9, wherein the electric wiring that energizes said plurality of LED elements forms a mesh-shaped circuit, and even when a part of the circuit is cut out, the circuit supplies a current to a remaining LED element through a path bypassing the cutout part.

14. The surface emitter according to claim 10, wherein the electric wiring that energizes said plurality of LED elements forms a mesh-shaped circuit, and even when a part of the circuit is cut out, the circuit supplies a current to a remaining LED element through a path bypassing the cutout part.

15. The surface emitter according to claim 7, wherein said top film is not only a transparent film but also is a material having a low transparency, such as an obscure glass sheet, a frosted glass sheet, an interior wallpaper, and a printed material.

16. The surface emitter according to claim 8, wherein said top film is not only a transparent film but also is a material having a low transparency, such as an obscure glass sheet, a frosted glass sheet, an interior wallpaper, and a printed material.

17. The surface emitter according to claim 9, wherein said top film is not only a transparent film but also is a material having a low transparency, such as an obscure glass sheet, a frosted glass sheet, an interior wallpaper, and a printed material.

18. The surface emitter according to claim 11, wherein said top film is not only a transparent film but also is a material having a low transparency, such as an obscure glass sheet, a frosted glass sheet, an interior wallpaper, and a printed material.

19. An internally illuminated sign, comprising:
a sign case having a sign front surface, a side plate and a back plate; and
a surface emitter installed in the sign case,
wherein said surface emitter comprises a flexible substrate having electric wiring, a plurality of LED elements disposed substantially regularly on the substrate, and a top film disposed on the LED elements in a stretched manner, and when said top film is disposed on the substrate in a stretched manner, the top film is applied to the substrate to come into close contact with projections and depressions formed by the LED elements.

20. The internally illuminated sign according to claim 19, wherein when said top film is disposed on the substrate in a stretched manner to come into close contact with the projections and depressions formed by the LED elements, a space between the LED elements and the top film is evacuated, and the top film is heated and pressure-bonded to the surface of the LED elements.

21. The internally illuminated sign according to claim 19, wherein said top film is a highly clingy and highly stretchable polyvinyl chloride film.

22. The internally illuminated sign according to claim 19, wherein the electric wiring that energizes said plurality of LED elements forms a mesh-shaped circuit, and even when a part of the circuit is cut out, the circuit supplies a current to a remaining LED element through a path bypassing the cutout part.

23. The internally illuminated sign according to claim 19, wherein said top film is not only a transparent film but also is a material having a low transparency, such as an obscure glass sheet, a frosted glass sheet, an interior wallpaper, and a printed material.
